(19) United States
(12) Patent Application Publication
(10) Pub. No.: US 2025/0258478 A1
(43) Pub. Date: Aug. 14, 2025

(54) APPARATUS AND METHOD FOR SUPPORTING LASER SYSTEM OPERATION BASED ON CENTRAL MANAGEMENT OF DRAWINGS USING CAD

(71) Applicant: DATECHNOLOGY CO., LTD, Hwaseong-si (KR)

(72) Inventor: Sun Geun CHO, Sacheon-si (KR)

(73) Assignee: DATECHNOLOGY CO., LTD, Hwaseong-si (KR)

(21) Appl. No.: 19/046,530

(22) Filed: Feb. 6, 2025

(30) Foreign Application Priority Data
Feb. 14, 2024 (KR) 10-2024-0021016

(51) Int. Cl. G05B 19/4097; B33Y 50/02; G06F 30/10

(52) U.S. Cl. CPC G05B 19/4097; B33Y 50/02; G06F 30/10; G05B 2219/33198

(57) ABSTRACT

An apparatus for supporting laser system operation based on central management of drawings using CAD, includes: a drawing control device configured to execute a CAD program, and using Visual Basic Application (VBA) on the CAD program, execute a program to extract drawing information and transmit the drawing information to a drawing information database through a network switch hub; a drawing information database configured to store the extracted drawing information transmitted from the drawing control device; a laser system control device configured to execute a laser control program and read processing history from the drawing information database to perform laser processing control; and a laser device configured to perform processing according to the drawing information using a laser system with the same name as each layer under control of the laser system control device.

### CROSS-REFERENCE TO RELATED PATENT APPLICATION

This application claims priority to Korean Patent Application No. 10-2024-0021016 (filed on Feb. 14, 2024), which is hereby incorporated by reference in its entirety.

### BACKGROUND

The present disclosure relates to laser scanner control, and more specifically, to an apparatus and a method for supporting laser system operation based on central management of drawings using CAD, which is capable of efficiently operating and managing files without a commercial CAD library by transmitting information on a drawing to be processed to a database of a central terminal by applying an internal program.

In general, processing using lasers has been done using a single scanner, but when using a single scanner, there is a limit to the processing speed, and there is a limit to large-area processing due to the limitations of the scanner's working area.

To solve this problem, the step & scanning method has been used, which is a method of processing with a scanner when the stage is stopped, and then moving the stage to the next step and processing with a scanner, which is a sequential processing method, and is slower than continuous processing, and the precision is reduced due to the occurrence of a seam due to discontinuous processing in the area before and after the stage moves.

In the case of a method of linking the stage and scanner to solve this problem of using a single scanner and the step-scan method, the CAD data of the entire processing drawing must be stored for processing, but large-area processing is impossible due to the limitations of the scanner control board's storage memory.

In general laser scanner control, drawing information is managed and controlled through a commercial library or a separate program by the developer, and laser scanner control is performed for each drawing.

Accordingly, in order to manage drawings for each equipment, this is a method of operating with drawing information for each equipment.

However, such conventional drawing management method for laser scanner control has the following problems.

There is a problem that drawings for laser scanner control must be managed (modified) separately, and properties for laser control for each equipment for the same drawing must be managed separately.

In addition, when developing a program, there is a cost for operating a separate CAD library, and there are restrictions on a specific format (extension: dwg) for drawing files for each development library.

In addition, there is a problem that one drawing must be divided to control the drawings for each part, and that laser control must be performed by modifying the CAD drawing in the equipment.

Therefore, there is a need for the development of new technologies that enable efficient file operation and management without commercial CAD libraries.

### PRIOR-ART DOCUMENTS

### Patent Documents

(Patent Document 1) Korean Patent Application Publication No. 10-2014-0080843
(Patent Document 2) Korean Patent No. 10-1074014
(Patent Document 3) Korean Patent No. 10-0403312

### SUMMARY

The present disclosure is to solve the problems of conventional drawing management and laser scanner control technologies, and an object is to provide an apparatus and a method for supporting laser system operation based on central management of drawings using CAD, which is capable of efficiently operating and managing files without a commercial CAD library by transmitting information on a drawing to be processed to a database of a central terminal by applying an internal program.

An object of the present disclosure is to provide an apparatus and a method for supporting laser system operation based on central management of drawings using CAD, which is capable of improving work efficiency and productivity by allowing users to modify drawings on CAD rather than in a separate library when changing drawings, thereby using CAD with which they are familiar.

An object of the present disclosure is to provide an apparatus and a method for supporting laser system operation based on central management of drawings using CAD, which is capable of centrally managing drawing information and information on various attribute values so that the same information may be used for equipment to be processed.

An object of the present disclosure is to provide an apparatus and a method for supporting laser system operation based on central management of drawings using CAD, which is capable of reducing costs by not requiring a separate CAD library when developing a program.

An object of the present disclosure is to provide an apparatus and a method for supporting laser system operation based on central management of drawings using CAD, which is capable of applying marking, ablation, etc., only with CAD's own drawing control function by enabling modification of drawings through CAD, thereby eliminating restrictions on formats.

An object of the present disclosure is to provide an apparatus and a method for supporting laser system operation based on central management of drawings using CAD, which is capable of controlling a drawing according to the name of each layer for one drawing, and performing a laser system control by modifying the drawing on the CAD program, thereby controlling multiple laser systems with one drawing, and immediately reflecting modifications to the drawing in the laser system control.

Other objects of the present disclosure are not limited to the objects mentioned above, and other objects not mentioned will be clearly understood by those skilled in the art from the description below.

An apparatus for supporting laser system operation based on central management of drawings using CAD according to the present disclosure to achieve the above described objects includes a drawing control device configured to execute a CAD program, and using Visual Basic Application (VBA) on the CAD program, execute a program to extract drawing information and transmit the drawing information to a drawing information database through a network switch hub; a drawing information database configured to store the extracted drawing information transmitted from the drawing control device; a laser system control device configured to execute a laser control program and read processing history from the drawing information database to perform laser processing control; and a laser device configured to perform processing according to the drawing information using a laser system with the same name as each layer under control of the laser system control device.

Here, the drawing control device is configured to read a drawing, match an equipment name and a layer name on the drawing with a laser name to be driven using the VBA on the CAD program, execute a zoom function on the CAD program, and read drawing information for all objects selected through a function of selecting all objects on the CAD program.

In addition, the drawing control device is configured to, while increasing a count by the number of drawing objects, repeatedly read information until the number of the drawing objects matches the count, read layer information, and verify whether the name is the same as the corresponding laser.

In addition, the drawing control device is configured to, when the layer name and the laser name are the same, verify a name of an object to extract corresponding object information according to the name of the object, and verify information about each object including layer information, coordinate information, and color information to enable storing the extracted drawing information in the drawing information database.

In addition, the drawing control device includes a CAD program executor configured to execute the CAD program, a drawing information extraction program executor configured to execute the program using the VBA on the CAD program, and a drawing information extractor and transmitter configured to extract the drawing information using the program executed by the drawing information extraction program executor and transmit the drawing information to the drawing information database through the network switch hub.

In addition, the drawing information extractor and transmitter includes a drawing loader configured to read a drawing by executing a program written using the VBA on the CAD program, a layer designator configured to match an equipment name and a layer name on the drawing with a laser name to be driven, a drawing selector and drawing information extractor configured to execute a zoom function, read drawing information for all objects selected through a function of selecting all objects on the CAD program, and while increasing a count by the number of drawing objects, repeatedly read information until the number of the drawing objects matches the count, a layer information verifier configured to read layer information to verify whether the name is the same as the corresponding laser, an object name verifier and information extractor configured to, when the layer name and the laser name are the same, verify a name of an object and extract object information according to the name of the object, and an extracted information merge storage configured to, when information about each object including layer information, coordinate information, and color information is verified, store the information in the database.

A method of supporting laser system operation based on central management of drawings using CAD according to the present disclosure to achieve the other objects includes executing a CAD program and using Visual Basic Application (VBA) on the CAD program to execute a program; reading a drawing and executing a drawing information extraction program to read drawing information for all selected objects and verify layer information and object names to extract drawing information; when information about each object including layer information, coordinate information, and color information is verified, storing the information in a database; executing a laser control program and reading processing history from a drawing information database; and performing processing according to the drawing information using a laser system with the same name as each layer under control of a laser system control device.

Here, tables of the database include a CAD information table configured to store the drawing information through a VBA function of the CAD program, an attribute information table for laser processing, and a table for laser basic information.

In addition, the CAD information table includes equipment name, drawing name, coordinate information, processing command information, and color information, and processing is performed by applying processing parameters based on the same color information as the CAD information of the attribute information table for laser processing.

The apparatus and method for supporting laser system operation based on central management of drawings using CAD according to the present disclosure as described above have the following effects.

First, it is possible to efficiently operate and manage files without a commercial CAD library by transmitting information on a drawing to be processed to a database of a central terminal by applying an internal program.

Second, it is possible to improve work efficiency and productivity by using CAD that is familiar to the user by allowing a drawing to be modified on CAD rather than in a separate library when changing a drawing.

Third, it is possible to centrally manage drawing information and information on various attribute values so that the same information may be used for equipment to be processed.

Fourth, it is possible to reduce costs by not requiring a separate CAD library when developing a program.

Fifth, it is possible to apply marking, ablation, etc., only with CAD's own drawing control function by enabling modification of drawings through CAD and eliminating restrictions on formats.

Sixth, it is possible to control a drawing according to the name of each layer for one drawing, and perform a laser system control by modifying the drawing on the CAD program, thereby controlling multiple laser systems with one drawing, and immediately reflecting modifications to the drawing in the laser system control.

### BRIEF DESCRIPTION OF THE DRAWINGS

FIG. 1 is a configuration diagram of an apparatus for supporting laser system operation based on central management of drawings using CAD according to the present disclosure.

FIG. 2 is a detailed configuration diagram of a drawing control device.

FIG. 3 is a detailed configuration diagram of a drawing information extractor and transmitter.

FIG. 4 is a flow chart illustrating a method of supporting laser system operation based on central management of drawings using CAD according to the present disclosure.

FIG. 5 is a configuration diagram illustrating a processing process according to a layer.

FIG. 6 is a configuration diagram of UML (class diagram).

FIG. 7 is a flow chart illustrating a transmission operation of CAD information to a database through execution of a drawing information extraction program.

FIG. 8 is a database structure diagram according to the present disclosure.

### DETAILED DESCRIPTION

Hereinafter, preferred embodiments of an apparatus and a method for supporting laser system operation based on central management of drawings using CAD according to the present disclosure will be described in detail as follows.

The features and advantages of the apparatus and method for supporting laser system operation based on central management of drawings using CAD according to the present disclosure will become apparent through detailed descriptions of each embodiment below.

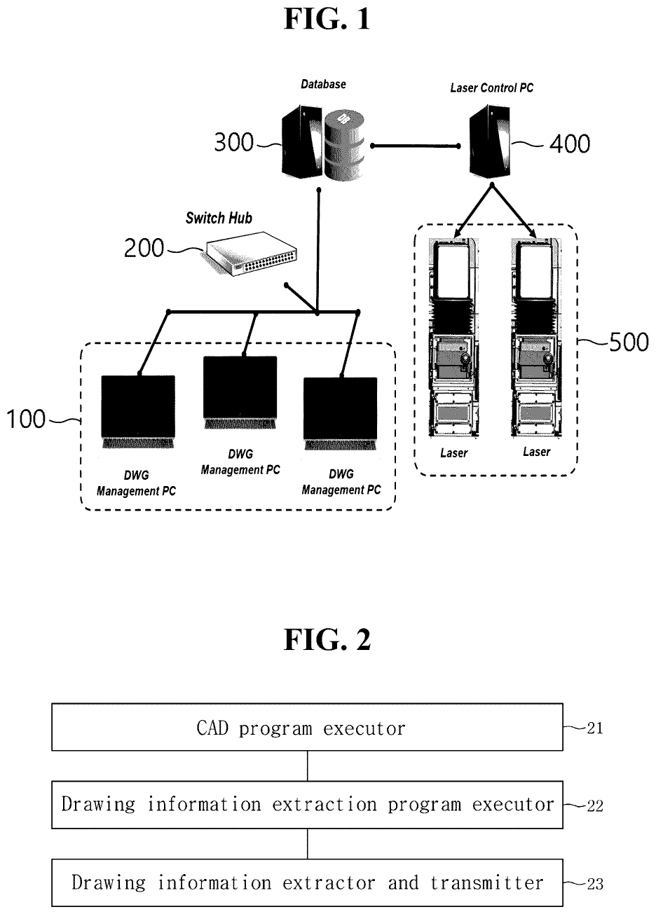

FIG. 1 is a configuration diagram of an apparatus for supporting laser system operation based on central management of drawings using CAD according to the present disclosure.

General terms that are currently widely used as much as possible have been selected as terms used in the present disclosure while considering the functions in the present disclosure, but this may vary depending on the intention of those skilled in the art, precedents, the emergence of new technologies, and the like. In addition, in certain cases, there are terms arbitrarily selected by the applicant, and in this case, the meaning will be described in detail in relevant parts of the detailed description. Therefore, the terms used in the present disclosure should be defined based on the meaning of the term and the overall content of the present disclosure, rather than simply the name of the term.

Throughout the specification, when a part “includes” a certain component, this means that it does not exclude other components but may additionally include other components, unless specifically stated to the contrary. In addition, terms such as “part” and “module” as used herein refer to a unit that processes at least one function or operation, which may be implemented as hardware or software, or as a combination of hardware and software.

In particular, units that process at least one function or operation may be implemented by an electronic device including at least one processor, and at least one peripheral device may be connected to the electronic device depending on the method of processing the function or operation.

The apparatus and method for supporting laser system operation based on central management of drawings using CAD according to the present disclosure is capable of efficiently operating and managing files without a commercial CAD library by transmitting information on a drawing to be processed to a database of a central terminal by applying an internal program.

To this end, the present disclosure may include a configuration that allows a drawing to be modified on CAD rather than in a separate library when changing a drawing, in order to increase work efficiency and productivity by using CAD that is familiar to the user.

The present disclosure may include a configuration that allows centrally managing drawing information and information on various attribute values so that the same information may be used for equipment to be processed.

The present disclosure may include a configuration that allows reducing costs by not requiring a separate CAD library when developing a program.

The present disclosure may include a configuration that allows applying marking, ablation, etc., only with CAD's own drawing control function by enabling modification of drawings through CAD and eliminating restrictions on formats.

The present disclosure may include a configuration that allows controlling a drawing according to the name of each layer for one drawing, and performing a laser system control by modifying the drawing on the CAD program, thereby controlling multiple laser systems with one drawing, and immediately reflecting modifications to the drawing in the laser system control.

As shown in FIG. 1, an apparatus for supporting laser system operation based on central management of drawings using CAD according to the present disclosure includes a drawing control device 100 configured to execute a CAD program, and using Visual Basic Application (VBA) on the CAD program, execute a program to extract drawing information and transmit the drawing information to a drawing information database 300 through a network switch hub 200, a drawing information database 300 configured to store the extracted drawing information transmitted from the drawing control device 100, a laser system control device 400 configured to execute a laser control program and read processing history from the drawing information database 300 to perform laser processing control, and a laser device 500 configured to perform processing according to the drawing information using a laser system with the same name as each layer under control of the laser system control device 400.

Here, the drawing control device 100 is configured to read a drawing, match an equipment name and a layer name on the drawing with a laser name to be driven using the VBA on the CAD program, execute a zoom function on the CAD program, and read drawing information for all objects selected through a function of selecting all objects on the CAD program.

In addition, the drawing control device 100 is configured to, while increasing a count by the number of drawing objects, repeatedly read information until the number of the drawing objects matches the count, read layer information, and verify whether the name is the same as the corresponding laser.

In addition, the drawing control device 100 is configured to, when the layer name and the laser name are the same, verify a name of an object to extract corresponding object information according to the name of the object, and verify information about each object including layer information, coordinate information, and color information to enable storing the extracted drawing information in the drawing information database 300.

The apparatus and method for supporting laser system operation based on central management of drawings using CAD according to the present disclosure creates a drawing through a user terminal using commercial CAD, and based on this, transmits the drawing information to the database through a program written using a program function on CAD (VBA: Visual Studio Application), and stores this in a central terminal.

In the equipment for processing, the information is accessed and read by the database on the central terminal where the information of the drawing is located, and the processing is carried out according to the information of the drawing based on the laser that is the same as the name of each layer, thereby increasing the productivity of the equipment, standardizing the drawing information, and centrally managing various attributes and information.

The present disclosure may be operated without a commercial CAD library, thereby reducing the development cost for the program, and may provide a method for easy file operation and management by using a familiar CAD during operation, thereby enabling various applications in laser control.

The detailed configuration of the drawing control device 100 is as follows.

FIG. 2 is a detailed configuration diagram of a drawing control device.

As shown in FIG. 2, the drawing control device 100 includes a CAD program executor 21 configured to execute the CAD program, a drawing information extraction program executor 22 configured to execute the program using the VBA on the CAD program, and a drawing information extractor and transmitter 23 configured to extract the drawing information using the program executed by the drawing information extraction program executor 22 and transmit the drawing information to the drawing information database 300 through the network switch hub 200.

The detailed configuration of the drawing information extractor and transmitter 23 is as follows.

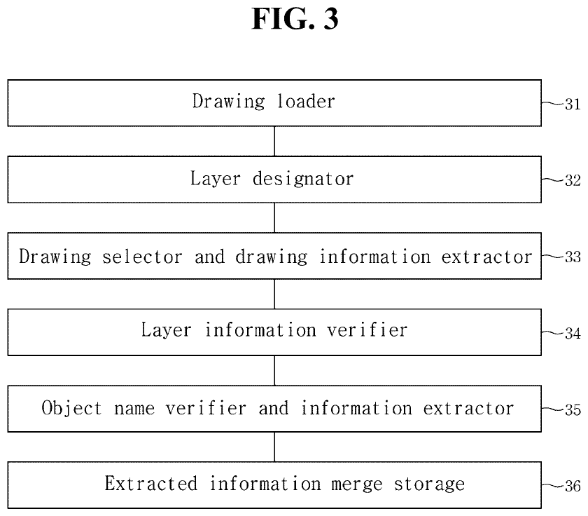

FIG. 3 is a detailed configuration diagram of a drawing information extractor and transmitter.

As shown in FIG. 3, the drawing information extractor and transmitter 23 includes a drawing loader 31 configured to read a drawing by executing a program written using the VBA on the CAD program, a layer designator 32 configured to match an equipment name and a layer name on the drawing with a laser name to be driven, a drawing selector and drawing information extractor 33 configured to execute a zoom function, read drawing information for all objects selected through a function of selecting all objects on the CAD program, and while increasing a count by the number of drawing objects, repeatedly read information until the number of the drawing objects matches the count, a layer information verifier 34 configured to read layer information to verify whether the name is the same as the corresponding laser, an object name verifier and information extractor 35 configured to, when the layer name and the laser name are the same, verify a name of an object and extract object information according to the name of the object, and an extracted information merge storage 36 configured to, when information about each object including layer information, coordinate information, and color information is verified, store the information in the database.

A method of supporting laser system operation based on central management of drawings using CAD according to the present disclosure is specifically described as follows.

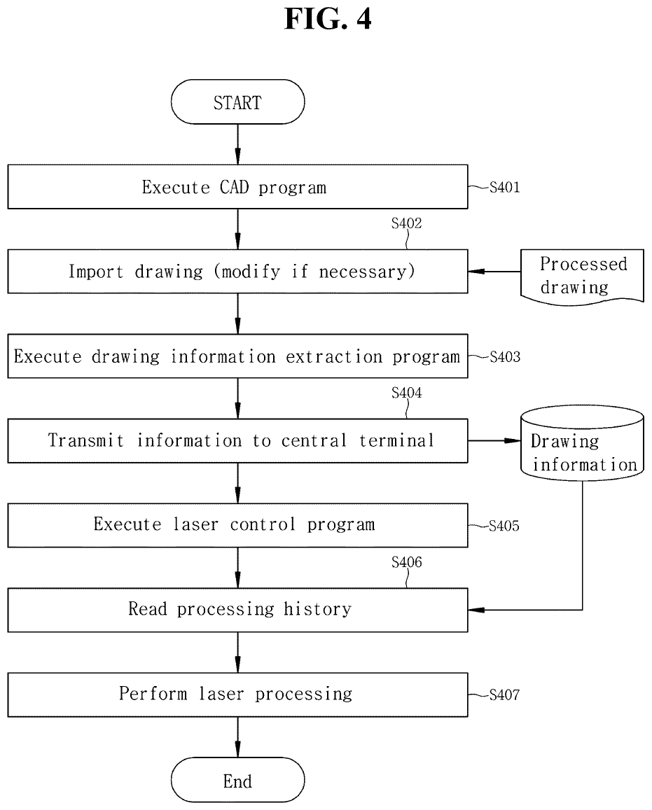

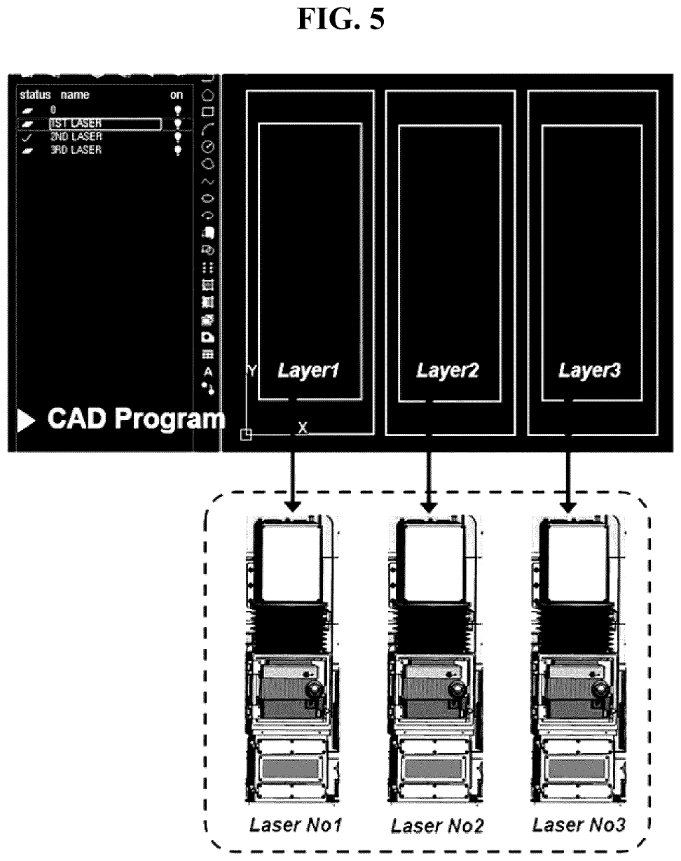

FIG. 4 is a flow chart illustrating a method of supporting laser system operation based on central management of drawings using CAD according to the present disclosure.

As shown in FIG. 4, the method of supporting laser system operation based on central management of drawings using CAD according to the present disclosure includes executing a CAD program and using Visual Basic Application (VBA) on the CAD program to execute a program written (S401).

Next, a drawing is read (S402) and a drawing information extraction program is executed to read drawing information for all selected objects and verify layer information and object names to extract drawing information (S403).

In addition, when information about each object including layer information, coordinate information, and color information is verified, the information is stored in a database (S404).

Next, a laser control program is executed (S405) and processing history is read from a drawing information database 300 (S406) and processing according to the drawing information is performed using a laser system with the same name as each layer under control of a laser system control device 400 (S407).

FIG. 5 is a configuration diagram illustrating a processing process according to a layer.

By classifying by layer on CAD, if the layer name is the same as the laser name, processing is performed accordingly, and multiple lasers may be controlled with a single drawing.

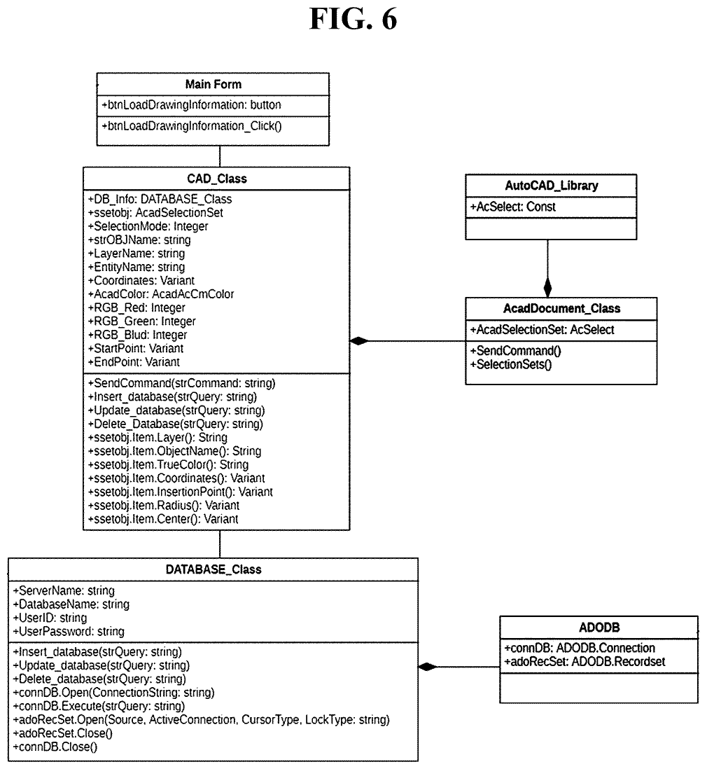

FIG. 6 is a configuration diagram of UML (class diagram).

UML (class diagram) is composed of a CAD class to read layer and entity information on CAD using AutoCad's library, and is composed of a database class to store the information on the database through ADODB.

In the laser control terminal, it accesses the database containing information for processing the corresponding drawing and performs processing for each Laser.

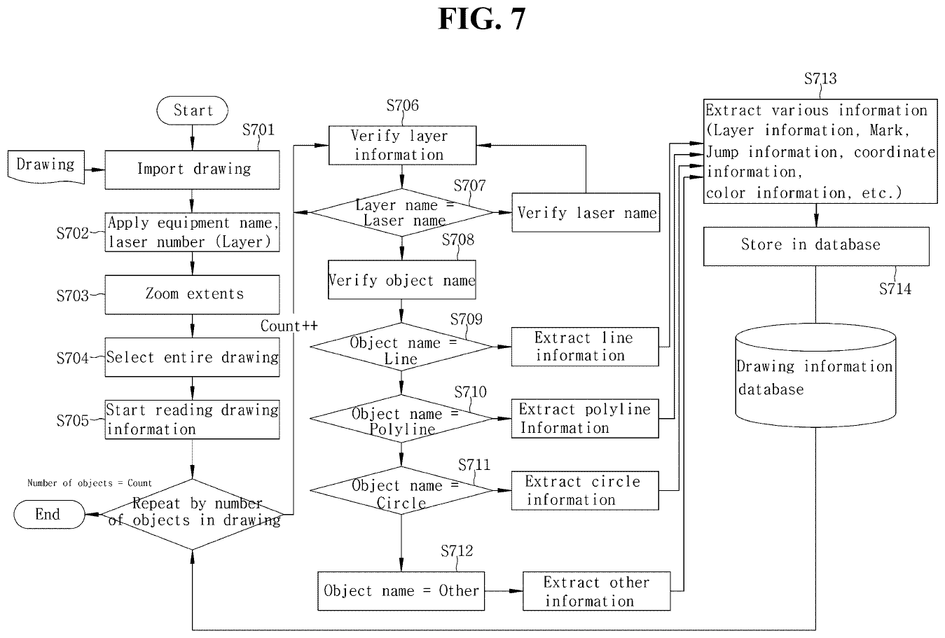

FIG. 7 is a flow chart illustrating a transmission operation of CAD information to a database through execution of a drawing information extraction program.

Transmission of CAD information to the database by executing the drawing information extraction program includes calling a drawing (S701), applying the equipment name and laser name (S702), performing zoom so that the entire drawing is visible (S703), selecting the entire drawing (S704), and reading it (S705).

Next, the layer information is verified (S706) and whether the name is the same as the corresponding laser is verified (S707).

Then, when the layer information name and the laser name are the same, the object name is verified and the object information is extracted according to the object name (S707 to S712).

Then, the information for each object including the layer information, coordinate information, and color information extracted through the object name verification and information extraction are merged (S713) and stored in the database (S714).

This process is repeated by the number of objects in the drawing, and after verifying the layer information, information for each object that matches the characteristics of each object is extracted. When the repetition is completed for the total number of objects, the CAD program is terminated.

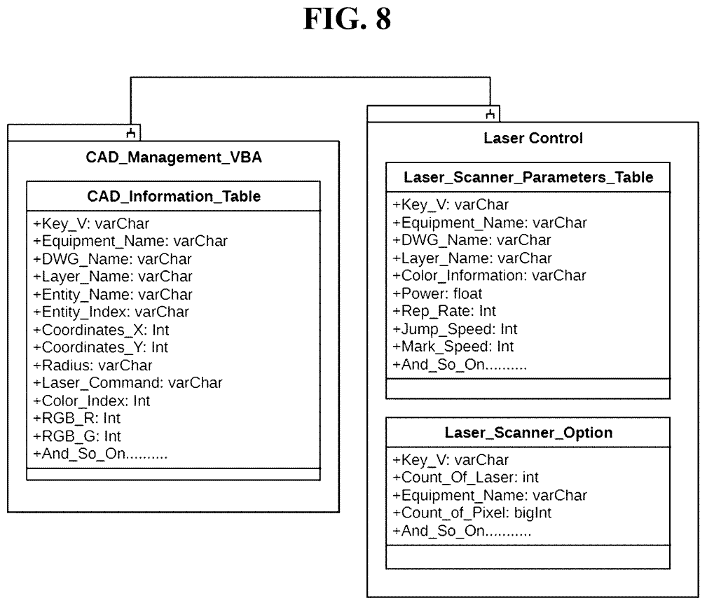

FIG. 8 is a database structure diagram according to the present disclosure.

The table of the database is composed of a CAD information table configured to store drawing information through the VBA function of CAD, an attribute information table for laser processing, a table for laser basic information, etc.

Information for processing on CAD and attribute information for laser processing are processed based on attributes of the same color based on the color of the drawing.

The CAD information table includes equipment name, drawing name, coordinate information, processing command information, color information, etc., and the attribute information table for laser processing applies processing parameters based on color information identical to the CAD information to perform processing.

The apparatus and method for supporting laser system operation based on central management of drawings using CAD according to the present disclosure described above is capable of efficiently operating and managing files without a commercial CAD library by transmitting information on a drawing to be processed to a database of a central terminal by applying an internal program.

The present disclosure improves work efficiency and productivity by using CAD that is familiar to the user by allowing a drawing to be modified on CAD rather than in a separate library when changing a drawing.

As described above, it will be understood that the present disclosure is implemented in a modified form without departing from the essential characteristics of the present disclosure.

Therefore, the specified embodiments should be considered from an illustrative rather than a restrictive perspective, and the scope of the present disclosure is indicated in the appended claims rather than the foregoing description, and all differences within the equivalent scope should be construed as being included in the present disclosure.

### EXPLANATION OF SYMBOLS

100. Drawing control device 200. Network switch hub
300. Drawing information database 400. Laser system control device
500. Laser device

1. An apparatus for supporting laser system operation based on central management of drawings using CAD, the apparatus comprising:
a drawing control device configured to execute a CAD program, and using Visual Basic Application (VBA) on the CAD program, execute a program to extract drawing information and transmit the drawing information to a drawing information database through a network switch hub;
a drawing information database configured to store the extracted drawing information transmitted from the drawing control device;
a laser system control device configured to execute a laser control program and read processing history from the drawing information database to perform laser processing control; and
a laser device configured to perform processing according to the drawing information using a laser system with the same name as each layer under control of the laser system control device.

2. The apparatus according to claim 1, wherein the drawing control device is configured to read a drawing, match an equipment name and a layer name on the drawing with a laser name to be driven using the VBA on the CAD program, execute a zoom function on the CAD program, and read drawing information for all objects selected through a function of selecting all objects on the CAD program.

3. The apparatus according to claim 2, wherein the drawing control device is configured to, while increasing a count by the number of drawing objects, repeatedly read information until the number of the drawing objects matches the count, read layer information, and verify whether the name is the same as the corresponding laser.

4. The apparatus according to claim 3, wherein the drawing control device is configured to, when the layer name and the laser name are the same, verify a name of an object to extract corresponding object information according to the name of the object, and verify information about each object including layer information, coordinate information, and color information to enable storing the extracted drawing information in the drawing information database.

5. The apparatus according to claim 1, wherein the drawing control device comprises:
a CAD program executor configured to execute the CAD program;
a drawing information extraction program executor configured to execute the program using the VBA on the CAD program; and
a drawing information extractor and transmitter configured to extract the drawing information using the program executed by the drawing information extraction program executor and transmit the drawing information to the drawing information database through the network switch hub.

6. The apparatus according to claim 5, wherein the drawing information extractor and transmitter comprises:
a drawing loader configured to read a drawing by executing a program written using the VBA on the CAD program;
a layer designator configured to match an equipment name and a layer name on the drawing with a laser name to be driven;
a drawing selector and drawing information extractor configured to execute a zoom function, read drawing information for all objects selected through a function of selecting all objects on the CAD program, and while increasing a count by the number of drawing objects, repeatedly read information until the number of the drawing objects matches the count;
a layer information verifier configured to read layer information to verify whether the name is the same as the corresponding laser;
an object name verifier and information extractor configured to, when the layer name and the laser name are the same, verify a name of an object and extract object information according to the name of the object; and
an extracted information merge storage configured to, when information about each object including layer information, coordinate information, and color information is verified, store the information in the database.

7. A method of supporting laser system operation based on central management of drawings using CAD, the method comprising:
executing a CAD program and using Visual Basic Application (VBA) on the CAD program to execute a program;
reading a drawing and executing a drawing information extraction program to read drawing information for all selected objects and verify layer information and object names to extract drawing information;
when information about each object including layer information, coordinate information, and color information is verified, storing the information in a database;
executing a laser control program and reading processing history from a drawing information database; and
performing processing according to the drawing information using a laser system with the same name as each layer under control of a laser system control device.

8. The method according to claim 7, wherein tables of the database comprise:
a CAD information table configured to store the drawing information through a VBA function of the CAD program;
an attribute information table for laser processing; and
a table for laser basic information.

9. The method according to claim 8, wherein the CAD information table comprises equipment name, drawing name, coordinate information, processing command information, and color information, and
processing is performed by applying processing parameters based on the same color information as the CAD information of the attribute information table for laser processing.
